(19) United States
(12) Patent Application Publication
(10) Pub. No.: US 2004/0240190 A1
(43) Pub. Date: Dec. 2, 2004

(54) Communication card and method of making the same

(76) Inventors: Ya-Wen Hsu, KaoHsiung (TW); Pao-Chien Kuo, HuaLien (TW); Shih-Ying Lin, Taipei (TW); Chung-Yi Lee, Hsinchu (TW); Chi-Chang Wang, Hsinchu (TW)

Correspondence Address: BIRCH STEWART KOLASCH & BIRCH, PO BOX 747, FALLS CHURCH, VA, 22040-0747, US

(21) Appl. No.: 10/751,401

(22) Filed: Jan. 6, 2004

(30) Foreign Application Priority Data
Jul. 29, 2003 (TW) 092120592
May 30, 2003 (TW) 092114657

(51) Int. Cl. H05K 7/14; H05K 7/18

(52) U.S. Cl. 361/797

(57) ABSTRACT

A communication card has a bottom panel, a top cover and a top panel, which is able to accommodate an electronic device. The electronic device has a circuit board and a RF transceiver coupling to the circuit board. The circuit board further comprises at least a metallic ground layer extending along the whole area of the circuit board, such that the dissipation of EMI from the backside of the circuit board can be prevented. The bottom panel and the top panel are both made of an electromagnetic wave penetrable material, and the top cover is made of an electromagnetic wave impenetrable material. The connecting means that can inter-engage with each other are respectively applied on the bottom panel and the top cover, and between the bottom panel and the top panel. After assembling, the circuit board is substantially positioned between the top cover and the bottom panel, and the RF transceiver is substantially positioned between the top panel and the bottom panel. Furthermore, a ring is formed on the bottom panel integrally for easily equipping with users.

### BACKGROUND

(a). Field of the Invention

The present invention relates to a communication card, especially to a wireless communication card with a circuit member and a method of making the same.

(b). Description of the Prior Arts

The expansion cards used in the computer (also called computer expansion card, which, in short, is addressed as communication card hereinafter) not only can provide the portable computer and other electronic appliances with function expansion capability, but also can enhance the usefulness thereof. Currently, there are many standard specifications for communication cards, e.g. the PCMCIA standard specification constructed by the Personal Computer Memory Card International Association (PCMCIA). The common expansion functions provided by the communication card include: fax modem card, network interface card, memory card, and wireless network interface card, etc.

The communication cards designed with standard specification must conform to the international regulations, such as exterior dimension, structural strength and electrical safety (e.g. electromagnetic interference shielding). In order to meet with those regulations, size and appearance cannot be the only consideration while designing the housing of communication card. The requirements of overall structure strength and of preventing electromagnetic interference (EMI) must also be considered. At the same time, if the communication card of the same specification can be manufactured using fewer components, lower production cost and better time-saving configuring method, the commercial competitiveness can be improved tremendously.

Nowadays, many PCMCIA communication card related techniques of different structures have been disclosed. However, every prior art has its own shortcomings.

For example, the housing of a conventional PCMCIA communication card generally comprises: a top cover and a bottom cover, which both are made of a stainless steel plate; an upper frame and a lower frame, which both are made of plastic. Wherein, the upper and lower frames are injection molded respectively onto the top cover and the bottom cover. Moreover, the two covers are welded together using sonic welding. The aforementioned structure not only requires many components, many production molds, and troublesome fabricating method, but also requires relatively higher manufacturing cost by using sonic welding and by using injection molding to mold the frames onto the stainless covers. In addition, since the stainless top and bottom cover wrap around the whole PCMCIA communication card completely, the electromagnetic wave inside the PCMCIA communication card is isolated by the stainless plate. Hence, the aforementioned prior arts are not applicable to be used in the wireless Communication card embedded with antenna for radio transmission.

Another example of the housing of another prior art PCMCIA communication card typically uses a grounding housing and a bottom panel both made of metal to wrap the circuit board for preventing EMI. Moreover, a plastic top panel which is injection molded onto the grounding housing is used for beautification. It is obvious that this prior art also suffers the shortcomings, such as requiring many production molds, requiring troublesome fabricating method and requiring relatively higher manufacturing cost by using injection molding to mold the plastic top panel onto the grounding housing. In addition, since the metallic grounding housing and the metallic bottom panel wrap around the whole PCMCIA communication card completely, hence, the aforementioned prior art is not applicable to be used in the wireless Communication card embedded with antenna for radio transmission.

Yet another prior art reveals a housing structure that is applicable for using in wireless Communication card. The housing structure uses supporting frame and top cover, which both are made of plastic, to wrap around the radio transmission components within the substrate for transmitting radio signals. And, the other part of the substrate is wrapped by using two metal plates for preventing EMI. Moreover, for preventing the electromagnetic wave dissipated from the seam between the two metal plates, the prior art further installs two metallic side bars to enhance the EMI preventing function. Obviously, the technique revealed in the prior art can solve the aforementioned applicability problem of the wireless Communication card. However, the use of six components, including supporting frame, top cover, two metal plates, and two side bars, will increase the costs, such as the developing cost for molds, the working-hour for configuration, and the manufacture cost, etc.

In addition, for having enough space to accommodate the electronic components and circuits required for the aforesaid communication cards to be able to support the increasingly complicated functional requirement, the printed circuit board (PCB) used in the communication card usually adopts multi-layer design. Please refer to FIG. 1, which is an exploded view of an electronic device used in a communication card according to prior arts. As seen in FIG. 1, the electronic device 100 containing the electronic components and circuit layout for providing wireless LAN communication function mainly comprises: a multi-layer PCB 130, at least a primary electronic component 110 and a RF transceiver 120, wherein the electronic component 110 and the RF transceiver 120 are both installed on the multi-layer PCB 130.

However, the multi-layer PCB 130 having a metallic layer 250 extending along the whole area of the PCB 130 for providing grounding function with reference to FIG. 2, which is a sectional view schematically showing the circuit board 130, will block a portion of radio signal 200 emitted from the RF transceiver 120 such that the quality of communication is affected. The removal of the portion of the metallic layer 250 under the projection of the RF transceiver 120 will result in a very complex manufacturing process and, in consequence, a higher production cost. Moreover, in order to prevent the occurrence of interference between the radio signal of the RF transceiver 120 and the electronic component 110 on the PCB 130, the RF transceiver 120 and the electronic component 110 should be separated by a predefined distance that will enlarge the surface area of the multi-layer PCB 130 required and further increase the cost of manufacturing.

Accordingly, all of the aforementioned prior arts require further improvement.

### SUMMARY OF THE INVENTION

The primary object of the present invention is to provide a communication card and a method of making the same that is simple and cost-effective.

Another object of the present invention is to provide a circuit member adaptable to a communication card, which has higher flexibility in circuit design and lower production cost.

Accordingly, the present invention provides a communication card adaptable to a slot of a host device for wireless communication. The communication card includes a circuit member, a first top surface member, a second top surface member, and a bottom surface member. The circuit member has a main portion and an RF portion. The rear end of the main portion connects to a connector. The front end of the main portion connects to the RF portion for radio frequency transmission. The first top surface member encloses the top surface of the main portion of the circuit member. The second top surface member engages with the first top surface member for enclosing the RF portion of the circuit member. The bottom surface member encloses the bottom surface of the circuit member by securing to the first top surface member and the second top surface member, the bottom surface member having a recess to engage with the first top surface member to form an opening adaptable to the connector.

Yet, the present invention further provides a circuit member adapted for the wireless communication card. The circuit member comprises: a first circuit member; a primary electronic component arranged on the first circuit member; a second circuit member electrically connected to the first circuit member and a RF transceiver arranged on the second circuit member.

Other and further features, advantages and benefits of the invention will become apparent in the following description taken in conjunction with the following drawings. It is to be understood that the foregoing general description and following detailed description are exemplary and explanatory but are not to be restrictive of the invention.

### BRIEF DESCRIPTION OF THE DRAWINGS

FIG. 1 is an exploded view of a printed circuit board used in a communication card according to prior arts.

FIG. 2 is a sectional view schematically showing the printed circuit board of FIG. 1.

FIG. 3 is an exploded view of the preferred embodiment of the present invention.

FIG. 4 is a sectional view showing a preferred embodiment of the circuit board of the present invention.

FIG. 5 is a sectional view schematically showing another preferred embodiment of the circuit board of the present invention.

FIG. 6 is a perspective view showing another preferred embodiment of PCB according to the present invention.

FIG. 7 is a sectional view schematically showing the printed circuit board of FIG. 6.

FIG. 8A is a top view of the multi-layer PCB 330 and the signal-layer PCB 340.

FIG. 8B is a front view and a top view showing the multi-layer PCB 330 electrically connected to the signal-layer PCB 340.

FIG. 9 is a rear view showing the top cover of the present invention.

FIG. 10 is an assembly drawing of the present invention.

FIG. 11 is a top perspective view of the present invention.

FIG. 12 is a bottom perspective view of the present invention.

FIG. 13 is an exploded drawing showing another preferred embodiment of the present invention.

FIG. 14 is a top perspective view showing another preferred embodiment of the present invention.

### DETAILED DESCRIPTION OF THE PREFERRED EMBODIMENTS

The communication card and the fabricating method thereof of the present invention are to employ a multi-layer printed circuit board (PCB) which has at least a layer of metallic layer extending along the whole surface of the circuit board for preventing the dissipation of EMI from the backside of the circuit board. Therefore, the communication card of the present invention only needs to use one metallic top cover to enclosure the upper side of the circuit board. On the other hand, the bottom of the circuit board and the RF transceiver portion can be supported and positioned respectively using the top panel and the bottom panel which are both made of plastic. The inter-embedding connecting mechanisms are installed between the top cover and the bottom panel, and also between the top panel and the bottom panel. Hence, the present invention requires only three components (including a metal member, such as a metal stamping member, and two plastic members, such as plastic injection molding members) to form an EMI preventing housing that is compatible with one or more standards, such as the PCMCIA standards.

The objects and spirits of the preferred embodiments according to the present invention will be readily understood by the accompanying drawings and detailed descriptions as following.

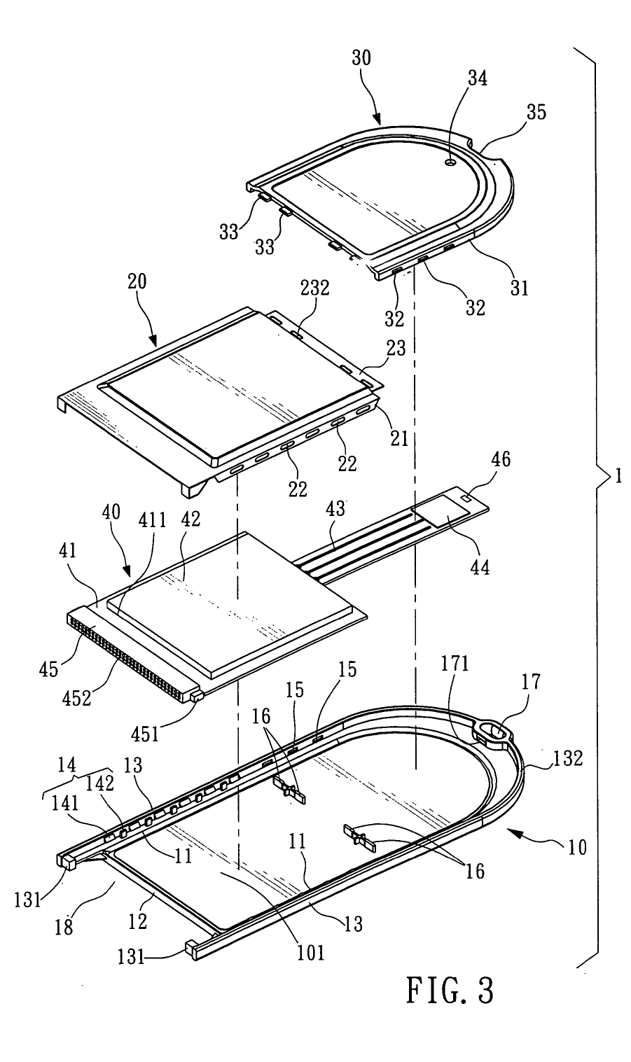

FIG. 3 is a 3-D exploded view of a communication card showing a preferred embodiment of the present invention. As shown, the communication card 1 comprises: a bottom panel 10 (also referred as a bottom surface member), a metallic top cover 20 (also referred as a first top surface member), a top panel 30 (also referred as a second top surface member) and an electronic device 40 (also can be simplified as a circuit board). In the present preferred embodiment, the communication card 1 is a wireless Communication card compatible with the PCMCIA standards.

The electronic device 40 contains the electronic components and circuit layout providing wireless LAN communication function, which comprises: a circuit board (also referred as a first circuit member) 41, a plurality of electronic components 42, an extending part (also referred as a second circuit member) 43, a RF (radio frequency) transceiver 44, a connector 45, and one or more indicating lights 46. The connector 45 compatible with one or more standards, such as PCMCIA standards, is located at a front side of the circuit board 41, and is used for connecting to an external device (not shown), such as a desktop computer, a notebook computer, a personal digital assistant (PDA), a cellular phone, or other electronic apparatuses with a slot adaptable to the communication card, etc. The plurality of electronic components 42 installed on the upper side 411 of the circuit board 41 are used for providing functions, such as wireless LAN communication, etc. The RF transceiver 44 uses the extending part 43 to couple with the plurality of electronic components 42 on the circuit board 41, wherein the digital signal received from the connector 45 is processed by the electronic device 40, and then is transmitted to the RF transceiver 44 for sending out a radio signal, on the other hand, the radio signal received by the RF transceiver 44 is processed by the electronic device 40, and then is transmitted to the external device via the connector 45. The indicating light 46 is employed as an indication of the status of power supply or signal receiving/transmitting. In the present preferred embodiment, the indicating light 46 can be a light emitting diode (LED) locating near the RF transceiver 44 and is coupled to the plurality of electronic components 42. When there is no external power supply existing (e.g. the connector 45 is not connecting to any external device), the indicating light 45 is not illuminating; on the contrary, when the connector 45 is connected to an external device and/or the RF transceiver 44 is receiving or transmitting radio signals, the indicating light 46 will remain illuminating, keep glittering, or perform color change.

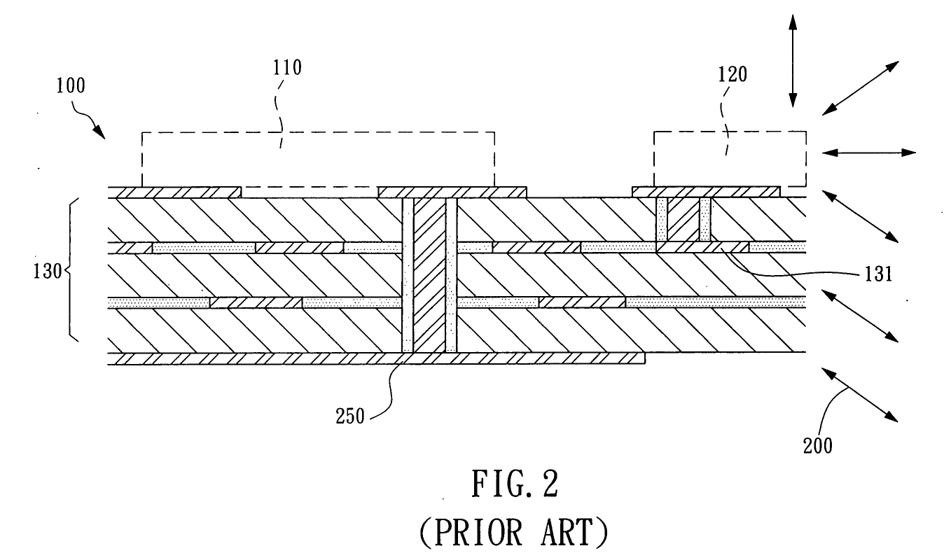

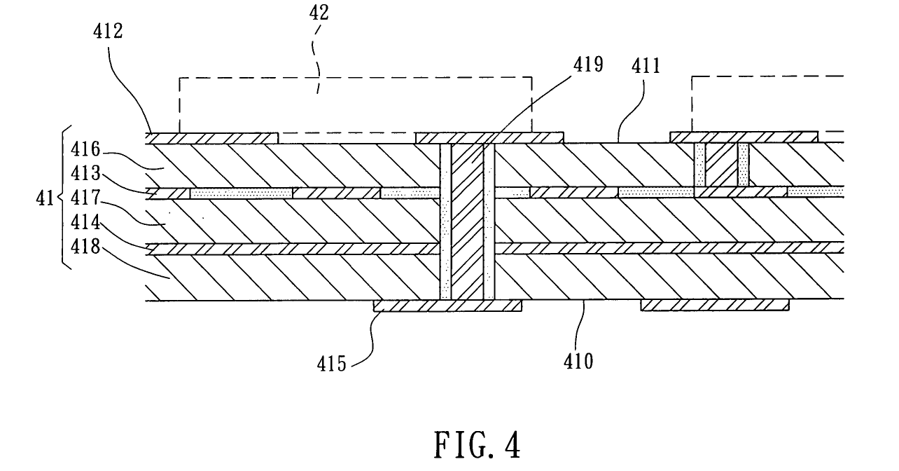

FIG. 4 is a sectional view showing a circuit board 41 embodiment of the present invention. In the present embodiment, The circuit board 41 of the electronic device 40 is a multi-layer circuit board having multiple metallic (e.g., copper) layers 412, 413, 414, 415. The circuit board is composed mainly of multiple overlapping metallic layers 412, 413, 414, 415 having insulation layers 416, 417, 418 between thereof (as seen in FIG. 2). In addition, each layer is able to connect to one another by way of the via 419. As shown in FIG. 4, the plurality of electronic components 42 are connected to the metallic layer 412 located at the upper side 411 of the circuit board 41. One metallic layer 414 of the multiple metallic layers of the circuit board 41 is extending horizontally along the whole area of the circuit board 41 for providing grounding function, so that the metallic layer 414 is called metallic grounding layer. In the present embodiment, the metallic layer 414 can prevent the dissipating electromagnetic wave emitting from the plurality of electronic component 42 from dissipating through the bottom side 410 of the circuit board 41 (which is the side that is opposite to the electronic components 42), so that the present invention has no need to install a metal plate or other EMI shielding material at the bottom side 410 of the circuit board 41 for isolating EMI.

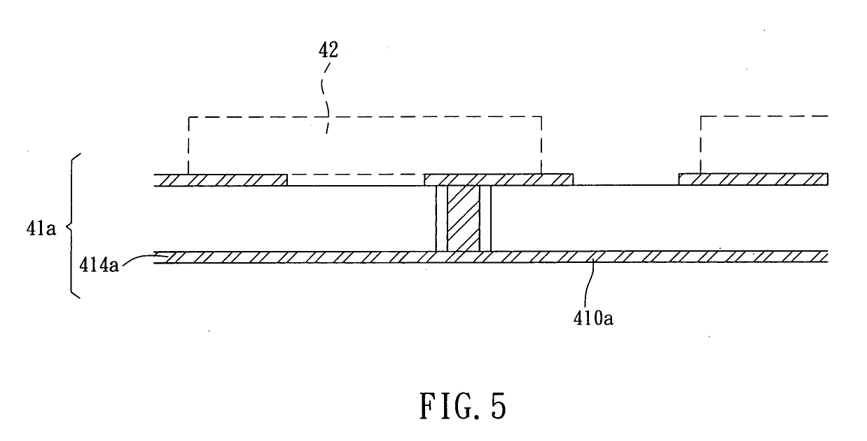

While the 4-layer circuit board 41 of the present invention has been shown and described with reference to a preferred embodiment thereof (as seen in FIG. 4), and in terms of the illustrative drawings, it should be not considered as limited thereby. That is, the circuit board 41 can be 2-layer, 6-layer, 8-layer or even other number of layers. Besides, the metallic layer 414 of the multiple layer circuit board is also not necessarily to be arranged in-between layers of the circuit board 41, and can be located at the bottom side 410 of the circuit board 41. As seen in FIG. 5., which is a diagram showing another circuit board 41a embodiment of the present invention, the metallic layer 414a is a layer formed on the bottom side 410a of the circuit board 41a having functions of grounding and EMI prevention.

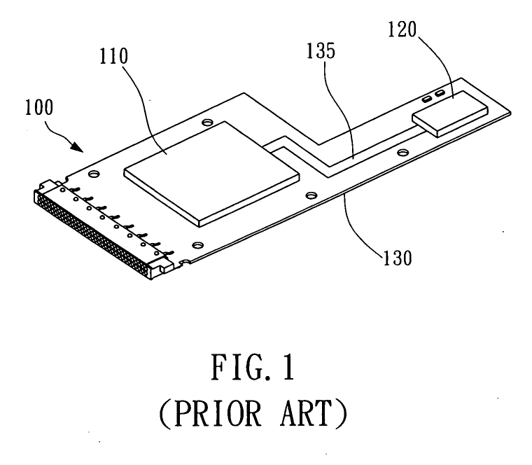

The RF transceiver 46 of the present invention is installed on the extending part 43 which can be integrally formed with the circuit board 41 to be a single body. However, in the present embodiment shown in FIG. 1, the extending part 43 is formed independently and connects electrically to the circuit board 41, the reasons for separately manufacturing the circuit board 41 and the extending part 43 include:

(1) In order to prevent the occurrence of interference between the radio signal of the RF transceiver 46 and the electronic component 43 on the circuit board 41, the RF transceiver 46 and the electronic component should be separated by a predefined distance;

(2) If the circuit board 41 and the extending part 43 are not made integrally, the circuit board 41 and the extending part 43 can be built respectively according to actual requirement of the layers of the circuit board so that the cost can be reduced;

(3) Since the circuit board 41 comprises a metallic layer 414 extending along the whole surface of the circuit board, the radio transmission effect will be reduced if the RF transceiver 46 is installed directly onto the circuit board 41 for the isolation created by the metallic layer 414.

Consequently, particularly in the present embodiment, the extending part 43 is used as a connection between the circuit board 41 and the RF transceiver 46, also flat cable or single layer circuit board can be used as the extending part 43 for the saving of cost. Of course, the extending part 43 can also be a multi-layer circuit board but having less layers than which of the circuit board 41.

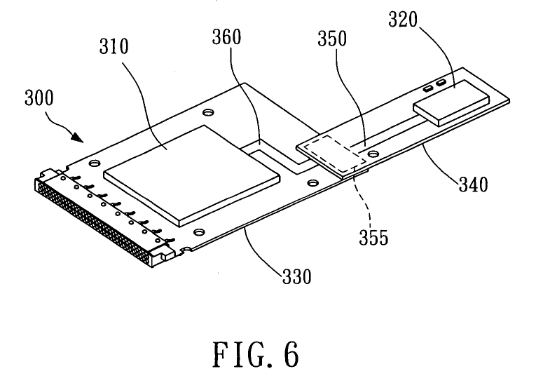

FIG. 6 is a top view showing another preferred embodiment of circuit board according to the present invention. As shown, the circuit board 300 includes a multi-layer circuit board 330 (also referred as the first circuit member hereinafter) and a single-layer circuit board 340 (also referred as the second circuit member hereinafter). The primary electronic component 310 and the RF transceiver 320 are respectively arranged on the first circuit member 330 and the second circuit member 340. The first circuit member 330 is electrically connected to the second circuit member 340 by a connecting means 355, and the primary electronic component 310 is electrically connected to the RF transceiver 320 by the circuitry 360, 350 respectively arranged on the first circuit member 330 and the second circuit member 340. The primary electronic component 310 is used for controlling the RF transceiver 320 to proceed with operations of wireless transmission, such as conversion between analog and digital signal, logic operation on digital data, and connection to other external device, etc., and can be composed of several different electronic devices.

Though the present embodiment illustrates the circuit board 300 in a communication card that is compatible with the PCMCIA standards as example, it should not be considered as limited thereby. The circuit board 300 can be applied in any wireless communication device having a primary electronic component 310 and a RF transceiver 320.

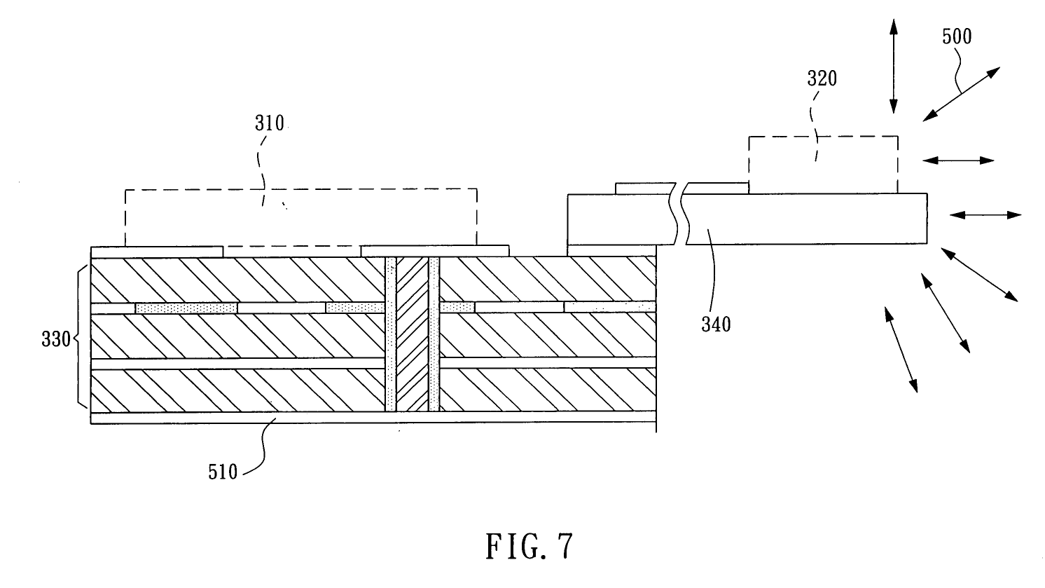

Please refer to FIG. 7, which is a sectional view showing the circuit board 300 of FIG. 6. As shown, the RF transceiver 320 is located on the portion of the second circuit member 340 that is not overlapping with the first circuit member 330. Thus, the metallic grounding layer 510 of the multi-layer first circuit member 330 (which is extending along whole area of the first circuit member 330) will not block the signal emitted from the RF transceiver 320.

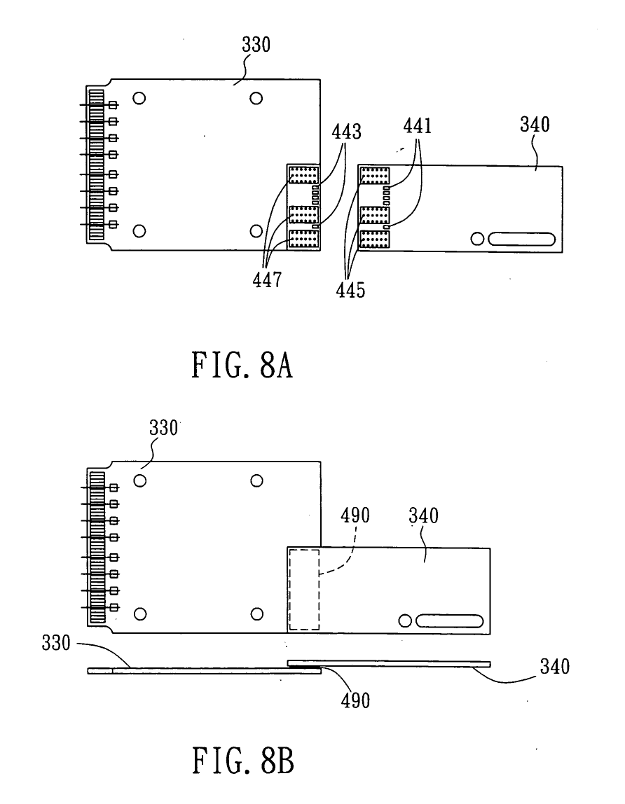

Please refer to FIG. 8A and FIG. 8B, which is top view showing an embodiment of an connecting means 490 for connecting the first circuit member 330 and the second circuit member 340 according to the present invention.

As shown in FIG. 8A, a plurality of signal pads 441, 443 and a plurality of welding pads 445, 447 are respectively arranged on the first circuit member 330 and the second circuit member 340. By coupling the signal pads 441 of the second circuit member 340 to the corresponding signal pads 443 of the first circuit member 330, the first circuit member 330 is electrically connected to the second circuit member 340. Moreover, the welding pads 445 and 447 form a welding area for fixing the two circuit members on one another. In addition, the connecting means 490 of FIG. 8B can be accomplished by surface mounting technology (SMT), plugging, or adhering, etc.

From the foregoing description with reference to FIG. 6 to FIG. 8A, the circuit board 300 of the present invention uses the circuit member 330, 340 both adopting module design for carrying the primary electronic component 310 and the RF transceiver 320 respectively. Wherein, the first circuit member 330 carrying the primary electronic component 310 can be a multi-layer circuit board, and the second circuit member 340 carrying the RF transceiver 320 can be a signal-layer circuit board or a flat cable. In another preferred embodiment of the present invention, the second circuit member 340 carrying the RF transceiver 320 can be a multi-layer circuit board having no metallic grounding layer, which has fewer layers than those of the circuit board carrying the primary electronic component. Since the RF transceiver is positioned on the second circuit member 340 where is not overlapped with the first circuit member 330, the metallic grounding layer of the first circuit member 330 will not block the signal emitting form the RF transceiver 320. Furthermore, while modifying the design of the circuit board 300, the modification can laid on either the first circuit member 330 or the second circuit member 340 and without the need to modify the whole structure.

As seen in FIG. 3, the bottom panel 10 is employed as a base for supporting, positioning, and combining the forgoing members (including the electronic device 40, the top cover 20 and the top panel 30). The size and shape of the bottom panel 10 is roughly equal to the sum of the top cover 20 and the top panel 30. The assembly of the bottom panel 10, the top cover 20 and the top panel 30 forms a housing having an encapsulating space therein for housing the electronic device 40.

The bottom panel 10 can be made of an electromagnetic wave penetrable material (which is called the first material hereinafter), e.g. plastic. The bottom panel 10 comprises: two side edges 11 extending along a lateral direction, a front edge 12 extending between the two side edges 11, two first flanges 13 respectively extending upwardly along the two side edges 11, a plurality of first connecting means 14 formed on the portion of the two first flanges which is close to the front edge 12, a plurality of second connecting means 15 formed on the portion of the two first flanges which is distant from the front edge 12, a plurality of ribs 16 located on an predetermined position of the bottom panel 10, and a ring 17. In the present preferred embodiment, the first connecting means 14 of the bottom panel 10 is composed of a plurality of hooks 141 and a plurality of bulges 142 which are interlaced with each other. The second connecting means 15 is a plurality of clipping holes on the two first flanges 13. The bulges 142 not only can enhance the structure strength of the first flanges 13, also the top of the bulges 142 can be used as a support to the lower rim of the hemmed edge 21 of the top cover 20 for preventing the top cover 20 from overly down-pressing. The front edge 12 further contains an opening 18 for accommodating the connector 45. When putting the electronic device 40 on a recessed portion 101 of the bottom panel 10, the connector 45 is just to be accommodated and positioned by the opening 18, so that the connector 45 along with the electronic device 40 can be positioned onto the predetermined position of the bottom panel 10. In the same time, the circuit board 41 are also positioned by the two first flanges 13 and the bulges 142. Simultaneously, the front portion 452 of the connector 45 is exposed through the opening 18 for connecting with an external device (not shown). Besides, the two sides of the opening 18 of the bottom panel 40 are respectively installed with a protrusion 131 that the two protrusions 131 block against the two bumps 451 on the two sides of the connector 45 for preventing the connector 45 from falling out of the opening 18. In addition, the slightly humping front edge 12 can prevent the connector 45 from drawing back inwardly into the bottom panel 10 (i.e. toward the right hand direction of FIG. 3).

In the present preferred embodiment, the two first flanges 13 are extending along and encircling part of the outer contour of the bottom panel, except for the front edge 12 and the opening 18. The rear portion 132 of the first flanges 13 of the bottom panel 10 can be formed as an arc shape as an illustration. The two first flanges 13 having a predefined thickness is able to provide structure of the whole communication card 1 with sufficient rigidity, as well as to compensate the shortcoming that the top cover 20 made of stamped metal sheet and the hemmed edge 21 thereof are easy to deform. The ring 17 which is integrally formed on the distal position of the bottom panel 10, so that users can pass a rope therethrough to hang the communication card 1 of the present invention on the neck of user.

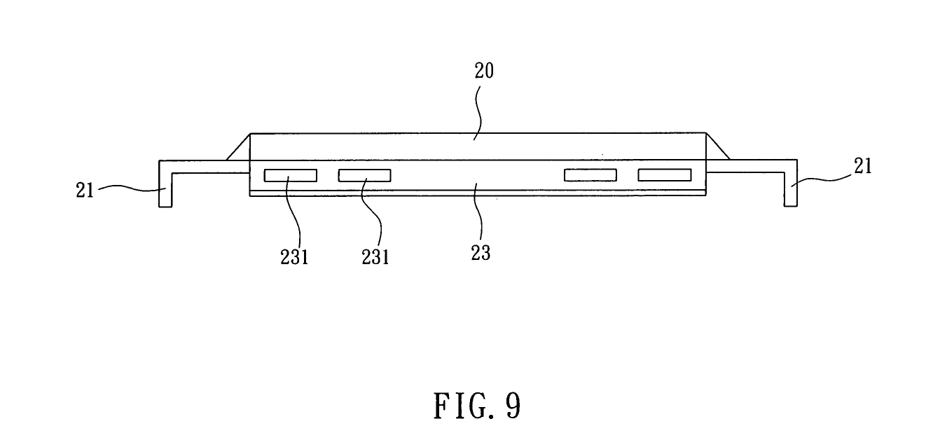

Please refer to FIG. 3 and FIG. 9, wherein FIG. 9 is a rear view showing the top cover 20 of the present invention. The top cover 20 is located at the position on the bottom panel 10 which is close to the front edge 12, and is made of an electromagnetic wave impenetrable material (which is called second material hereinafter), such as stamped stainless steel. The top cover 20 comprises: two hemmed edges 21 which are bended and extending along the lateral direction, a third connecting means 22 which is installed on the two hemmed edges 21, and a protruding rim 23 which is bended as a L-shape in a sectional view thereof. The third connecting means 22 is capable of interlocking/engaging with the hooks 141 of the first connecting means 14 so as to affix the top cover 20 to the bottom panel 10 at the position close to the front edge 12. In the present preferred embodiment, the third connecting means 22 is composed of a plurality of first clipping holes located on the two hemmed edges 21 for exactly inter-engaging with the plurality of hooks 141 on the bottom panel 10. The bended protruding rim 23 is arranged at the rear side of the top cover 20 close to the top panel 30, and is formed as an L shape by firstly bending a predefined length of the metallic plate of the top cover 20 at the aforementioned side downwardly (i.e. toward the bottom panel), and then bending again the forgoing downward-bended metallic plate having another predefine length horizontally extended (i.e. parallel to the top cover). The protruding rim 23 further comprises a plurality of embedding holes 231 (arranged on the downward-bending portion) and a plurality of positioning holes 232 (arranged on the horizontal-extending portion).

The top panel 30 is made of electromagnetic wave penetrable material and is formed integrally. The top panel 30 is located at the position on the bottom panel 10 farther to the front edge 12. The top panel 30 comprises: two second flanges 31 extending along the lateral direction and protruding downwardly, a fourth connecting means 32 installed on the two second flanges 31, one or more protrusions 33, a through hole 34, and a notch 35. The fourth connecting means 32 is capable of interlocking with the second connecting means 15 to affix the top panel 30 to the bottom panel 10 at the position away from the front edge 12. In the present preferred embodiment, the fourth connecting means 32 comprises of a plurality of clasps located on the two second flange 31 for inter-engaging with the plurality of the second clipping holes (which are arranged on the second connecting means 15) on the bottom panel 10. The protrusions 33 of the top panel 30 are arranged on the front side of the top panel 30 which is close to the top cover 20 for mating with the embedding holes 231 of the top cover 20 so as to affix the top panel 30 and the top cover 20. The position of the through hole 34 is corresponding to the indicating light 46. The position and shape of the notch 35 is corresponding to the ring 17. The ring 17 further has a dismantling hole 171 which is located at the position close to the top panel 30, so that the end of the top panel 30 can be picked up and separated from the bottom panel 10 by inserting and twisting a tool (such as a small I-shaped screw driver) inside the dismantling hole 171 for the purpose of disassembling the housing of the communication card 1.

The position of the plural ribs 16 on the bottom panel 10 is corresponding to the plural positioning holes 232 of the top cover 20, and the upper surface of the ribs 16 can contact with the bottom surface of the top panel 30. The engagement of the ribs 16 and the positioning holes 232 not only can support and position the top cover 20, also the top surface of the ribs 16 can support the bottom surface of the top panel 30 and prevent the deformation of the top panel 30 and the protruding rim 23 of the top cover 20.

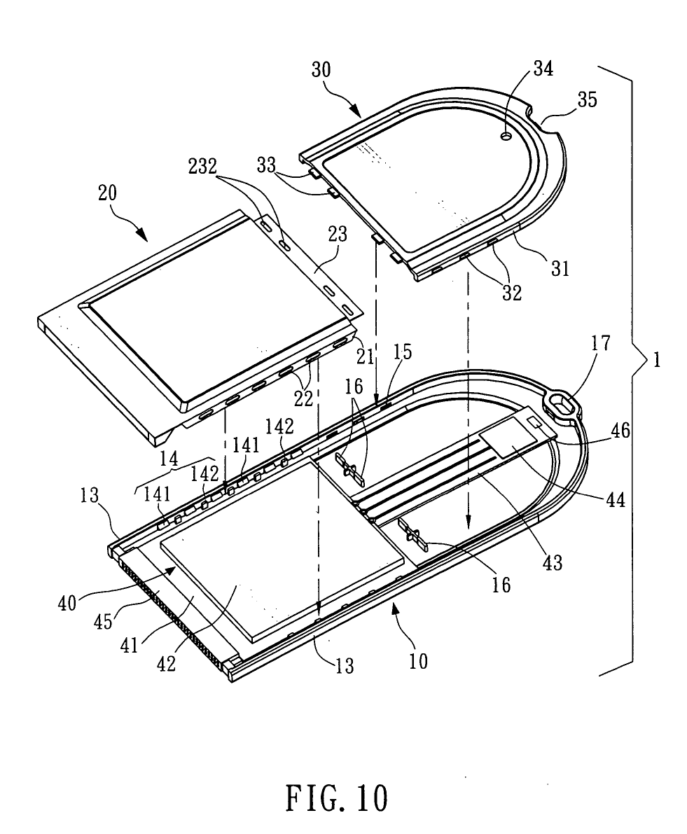

Please refer to FIG. 10, which is an assembly drawing of the communication card 1 according to the present invention. While assembling the communication card 1 of the present invention, first, the electronic device 40 is positioned in the predetermined position of the bottom panel 10, and the connector 45 of the electronic device 40 is deposited on the front edge 12 of the bottom panel 10, moreover, the RF transceiver 44 is positioned at the other side of the bottom panel 10 which is away from the front edge 12. Secondly, the top cover 20 is pressed into the bottom panel 10 so that the first connecting means 14 can inter-engage with the corresponding third connecting means 22, moreover, the plural electronic components 42 of the circuit board 41 are deposited between the top cover 20 and the bottom panel 10. Furthermore, the top panel 30 is tilted (preferably 20-60 degrees) to contact the protruding rim 23 of the top cover 20, so that the protrusions 33 are inserted into the embedding holes 231 of the top cover 20, and then the other end (rear) is pressed into the bottom panel 10, so that the second connecting means 15 can inter-engage with the corresponding fourth connecting means 32, moreover, the RF transceiver 44 is arranged between the top panel 30 and the bottom panel 10.

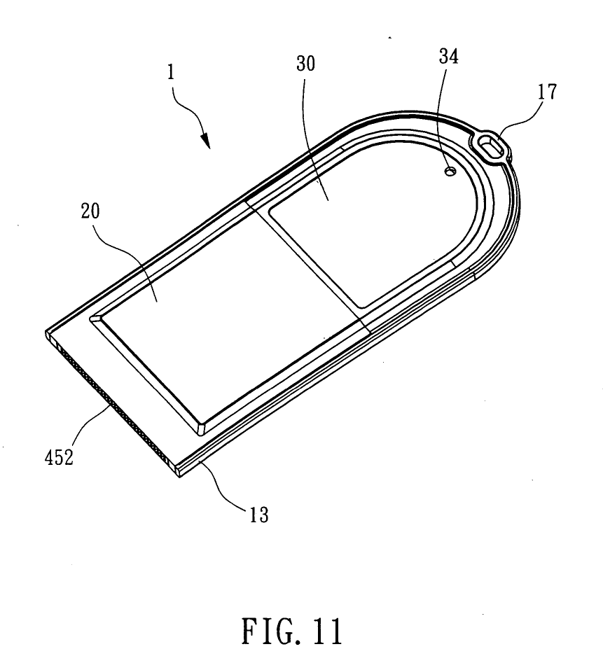

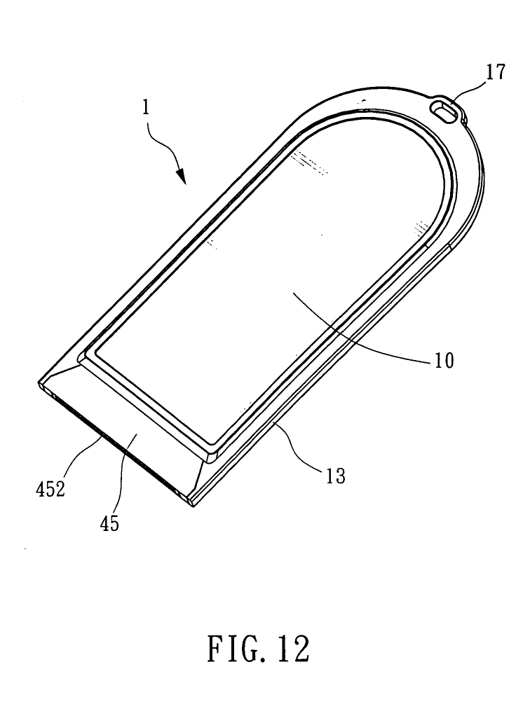

Please refer to FIG. 11 and FIG. 12, which respectively are a top and bottom perspective view showing an assembled communication card 1 of the present invention.

After assembling the communication card 1 of the present invention, the circuit board 41 and the plural electronic components 42 will be shielded by the top cover 20, the two hemmed edges 21 of the top cover 20, and the metallic layer 414 within the circuit board 41. Therefore, the upper side and the bottom side of the circuit board 41, and even including the two lateral sides thereof are shielded that the leakage of EMI is prevented. Nevertheless, the RF transceiver 44 arranged between the plastic top panel 30 and the bottom panel 10 is able to receive/transmit radio signals.

To disassemble the communication card 1 of the present invention, same as the aforementioned, the user can simply inserts and twists a tool (such as a small I-shaped screw driver) inside the dismantling hole 171 of the ring 17 to pick up the end of the top panel 30, so that the top panel 10 can be separated from the bottom panel 10. Following, the top panel 10, the top cover 20 and the electronic device 40 can be disassembled successively.

For clarity, since the other preferred embodiments hereinafter will have similar or the same components of the foregoing embodiment, therefore, for those same or similar components without giving further detail description will be given the same denomination and numbering that the only different is to add an English character to the original numbering for distinguishing.

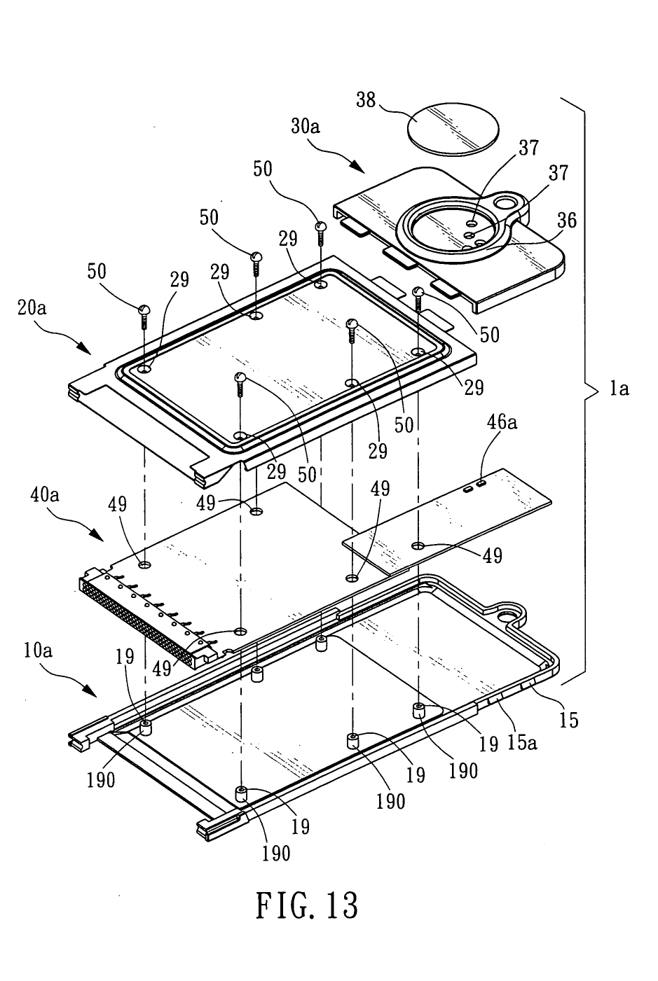

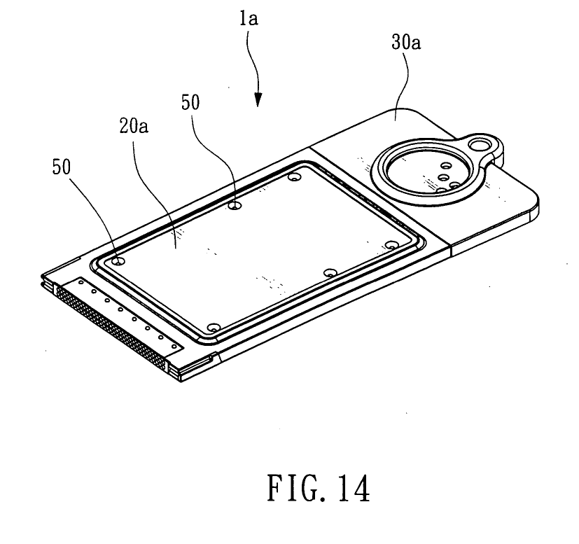

Please refer to FIG. 13, and FIG. 14, which are drawings showing the second embodiment of the communication card 1a in accordance with the present invention. Wherein, FIG. 13 is an exploded drawing showing the second embodiment of the communication card 1a of the present invention. FIG. 14 is a top perspective view showing the assembled appearance of second embodiment of the communication card 1a. The communication card 1a shown in FIGS. 13 and 14 also comprises: a bottom panel 10a, a top cover 20a, a top panel 30a, and an electronic device 40a. Since the material used, the structure and the composition of the bottom panel 10a, the top cover 20a, the top panel 30a and the electronic device 40a in the present embodiment are mostly similar to or the same as the ones of the foregoing embodiment with reference to FIG. 3, therefore, further details will not be given to those components, the following description will be only directed to those are different.

As seen in FIG. 13, the first connecting means and the third connecting means are not employed in the present second embodiment for connecting the bottom 10a and the top cover 20a, rather the communication card 1a of the present embodiment installs respectively a plurality of screw holes 19, 29, 49 on the corresponding locations of the top panel 10a, the top cover 20a and the electronic device 40a. By a plurality of screws 50 inserting from the top cover 20a to the bottom 10a, not only the top cover 20a and the bottom 10a can be assembled, also the electronic device 40a can be clamped between the top cover 20a and the bottom panel 10a. In the present embodiment, the screw holes 19 can be through hole or blind hole locating in the center of bosses 190 formed on the bottom panel 10a. Otherwise, the screw holes 19 can be molded into insert nuts in advance for preventing the crush of the threads inside the screw holes 19, so that the rigidity and durability of screw holes 19 can be increased. In addition, the ribs are not applied in the present embodiment since the bosses 190 can provide the electronic device 40a and the top cover 20a with supporting force.

Moreover, in the present second embodiment, an additional circular area 36 having a plurality of through holes 37 at the bottom thereof is formed on the top panel 30a, wherein one or more through holes 37 are adaptable to one or more indicating lights 46a. A plate 38 which is transparent, or semi-transparent, or partial transparent is embedded into or adhered on the circular area 36, and optionally can be printed with trademark, logo, pattern, or instructions related to the communication card 1a, etc. In yet another embodiment, the plate 38 also can be made out of light-diffusion material, such as acrylic, etc.

Further, in the present second embodiment, the corresponding second connecting means 15a and the fourth connecting means 32a are still employed for engaging the bottom panel 10a with the top panel 30. The difference between the first embodiment (shown in FIG. 3) and the second embodiment with reference to FIG. 13 is that the second connecting means 15a of the bottom panel 10a are hooks, and the fourth connecting means 32a of the top panel 30a are clipping holes. The other components of the communication card 1a according to the present second embodiment are similar to or the same as those of the first embodiment and therefore no further description is provided herein.

While the present invention has been shown and described with reference to a preferred embodiment thereof, and in terms of the illustrative drawings, it should be not considered as limited thereby. Various possible modification, omission, and alterations could be conceived of by one skilled in the art to the form and the content of any particular embodiment, without departing from the scope and the sprit of the present invention.

What is claimed is:

1. A communication card adaptable to a slot of a host device for wireless communication, comprising:
a circuit member having a main portion and an RF portion, a rear end of said main portion connecting to a connector and a front end of said main portion connecting to said RF portion;
a first top surface member enclosing a top surface of said main portion of said circuit member;
a second top surface member engaged with said first top surface member for enclosing said RF portion of said circuit member; and
a bottom surface member enclosing a bottom surface of said circuit member by securing to said first top surface member and said second top surface member, said bottom surface member having a recess to engage with said first top surface member to form an opening adaptable to said connector.

2. The communication card of claim 1, wherein said bottom surface member is made of plastic.

3. The communication card of claim 1, wherein said first top surface member is made of metal.

4. The communication card of claim 1, wherein said first top surface member is made of electromagnetic wave impenetrable material.

5. The communication card of claim 1, wherein said second top surface member is made of plastic.

6. The communication card of claim 1, wherein a front end of said bottom surface member is formed with a through hole.

7. The communication card of claim 1, further comprising: one or more indicating light.

8. The communication card of claim 1, wherein said bottom surface member further comprises:
a plurality of ribs formed as a single unit with said bottom surface.

9. The communication card of claim 1, wherein said connector is compatible with one or more PCMCIA standards.

10. The communication card of claim 1, wherein said circuit member is a printed circuited board.

11. The communication card of claim 1, wherein said circuit member comprises:
a first circuit member within said main portion;
a primary electronic component arranged on said first circuit member;
a second circuit member being within said RF portion and electrically connected to said first circuit member; and
a RF transceiver arranged on a area of said second circuit member for not overlapping with said first circuit member.

12. A method of making a communication card of claim 1, comprising:
providing a bottom surface member, a first top surface member, a second top surface member, and a circuit member;
securing said first top surface member to a rear end of said bottom surface member; and
securing said second top surface member to said first top surface member and a front end of said bottom surface.

13. A circuit member adapted for a communication card, comprising:
a first circuit member;
a primary electronic component arranged on said first circuit member;
a second circuit member electrically connected to said first circuit member; and
a RF transceiver arranged on a area of said second circuit member for not overlapping with said first circuit member.

14. The circuit member of claim 13, wherein said first circuit member is a multi-layer printed circuit board having a metallic grounding layer extending along a whole area of said first circuit member.

15. The circuit member of claim 14, wherein said second member is a multi-layer printed circuit board with fewer layers than those of said first printed circuit board.

16. The circuit member of claim 13, wherein said second circuit member is a multi-layer printed circuit board without a metallic grounding layer.

17. The circuit member of claim 13, wherein said second circuit member is a single-layer printed circuit board.

18. The circuit member of claim 13, wherein said second circuit member is a flat cable.

19. The circuit member of claim 13, further comprising:
a connector for connecting said first and second circuit members.

20. The circuit member of claim 19, wherein said connector is compatible with one or more PCMCIA standards.
